(19) United States
(12) Patent Application Publication
(10) Pub. No.: US 2025/0116687 A1
(43) Pub. Date: Apr. 10, 2025

(54) SENSOR DEVICES, METHODS FOR MANUFACTURING THEREOF, AND METHODS FOR SENSING ELECTRICAL CURRENTS

(71) Applicant: Infineon Technologies AG, Neubiberg (DE)

(72) Inventors: Gernot BINDER, Klagenfurt (AT); Thomas HAFNER, Magdalensberg (AT); Christoph KRALL, Klagenfurt (AT); Simone FONTANESI, Villach (AT); Johannes GÜTTINGER, Lind ob Velden (AT)

(21) Appl. No.: 18/905,524

(22) Filed: Oct. 3, 2024

(30) Foreign Application Priority Data
Oct. 4, 2023 (DE) 102023127013.3

(51) Int. Cl. G01R 19/10; G01R 19/00; G01R 33/00; G01R 33/09

(52) U.S. Cl. CPC G01R 19/10; G01R 19/0053; G01R 33/091; G01R 33/0052

(57) ABSTRACT

A sensor device includes an electrically conductive carrier and a magnetic field sensor mounted on the electrically conductive carrier. The magnetic field sensor includes a first pair of first sensing elements configured to provide a first differential signal representative of a magnetic field generated by an electrical current through an electrical conductor and by eddy currents generated in the electrically conductive carrier. The magnetic field sensor further includes a second pair of second sensing elements configured to provide a second differential signal representative of a magnetic field generated by the eddy currents and independent of a magnetic field generated by the electrical current through the electrical conductor. The sensor device further includes a unit configured to provide an output signal based on a difference or a sum including the first differential signal and the second differential signal.

### CROSS-REFERENCE TO RELATED APPLICATION

This application claims priority to Germany Patent Application No. 102023127013.3 filed on Oct. 4, 2023, the content of which is incorporated by reference herein in its entirety.

### TECHNICAL FIELD

The present disclosure relates to sensor devices and methods for manufacturing sensor devices. In addition, the present disclosure relates to methods for sensing electrical currents.

### BACKGROUND

Magnetic field sensors may be used for sensing electrical currents flowing through electrical conductors, such as e.g., PCB tracks or busbars. Time-variation of the electrical currents may result in eddy currents induced in electrically conductive components of the sensor device, such as e.g., in a leadframe. These unwanted eddy currents may deteriorate the measurement signal of the sensor device. At worst, eddy currents induced in a leadframe of the sensor device may result in degraded accuracy and/or undesired events like unintended overcurrent detection activation. Manufacturers and designers of sensor devices are constantly striving to improve their products. In particular, it may be desirable to develop sensor devices providing measurement results independent of induced eddy currents. In addition, it may be desirable to provide methods for manufacturing such sensor devices and methods for sensing electrical currents that may be performed by such sensor devices.

### SUMMARY

An aspect of the present disclosure relates to a sensor device. The sensor device includes an electrically conductive carrier and a magnetic field sensor mounted on the electrically conductive carrier. The magnetic field sensor includes a first pair of first sensing elements configured to provide a first differential signal representative of a magnetic field generated by an electrical current through an electrical conductor and by eddy currents generated in the electrically conductive carrier. The magnetic field sensor further includes a second pair of second sensing elements configured to provide a second differential signal representative of a magnetic field generated by the eddy currents and independent of a magnetic field generated by the electrical current through the electrical conductor. The sensor device further includes a unit configured to provide an output signal based on a difference or a sum including the first differential signal and the second differential signal.

A further aspect of the present disclosure relates to a sensor device. The sensor device includes an electrically conductive carrier and a magnetic field sensor mounted on the electrically conductive carrier. The magnetic field sensor includes a first pair of first sensing elements configured to provide a first differential signal, wherein the first sensing elements are separated from each other in a first direction, and wherein each of the first sensing elements is sensitive to magnetic fields in the first direction. The magnetic field sensor further includes a second pair of second sensing elements configured to provide a second differential signal, wherein the second sensing elements are separated from each other in a second direction perpendicular to the first direction, and wherein each of the second sensing elements is sensitive to magnetic fields in the second direction. The sensor device further includes a unit configured to provide an output signal based on a difference or a sum including the first differential signal and the second differential signal.

A further aspect of the present disclosure relates to a method for sensing an electrical current through an electrical conductor by a magnetic field sensor mounted on an electrically conductive carrier. The method includes an act of sensing, by a first pair of first sensing elements of the magnetic field sensor, a first differential signal representative of a magnetic field generated by the electrical current through the electrical conductor and by eddy currents generated in the electrically conductive carrier. The method further includes an act of sensing, by a second pair of second sensing elements of the magnetic field sensor, a second differential signal representative of a magnetic field generated by the eddy currents and independent of a magnetic field generated by the electrical current through the electrical conductor. The method further includes an act of providing an output signal based on a difference or a sum including the first differential signal and the second differential signal.

A further aspect of the present disclosure relates to a method for manufacturing a sensor device. The method includes an act of producing a magnetic field sensor. Producing the magnetic field sensor includes an act of producing a first pair of first sensing elements configured to provide a first differential signal, wherein the first sensing elements are separated from each other in a first direction, and wherein each of the first sensing elements is sensitive to magnetic fields in the first direction. Producing the magnetic field sensor further includes an act of producing a second pair of second sensing elements configured to provide a second differential signal, wherein the second sensing elements are separated from each other in a second direction perpendicular to the first direction, and wherein each of the second sensing elements is sensitive to magnetic fields in the second direction. Producing the magnetic field sensor further includes an act of producing a unit configured to provide an output signal based on a difference or a sum including the first differential signal and the second differential signal. The method further includes an act of providing an electrically conductive carrier. The method further includes an act of mounting the magnetic field sensor on the electrically conductive carrier.

### BRIEF DESCRIPTION OF THE DRAWINGS

Devices and methods in accordance with the disclosure are described in more detail below based on the drawings. Similar reference numerals may designate corresponding similar parts. The technical features of the various illustrated examples may be combined, provided they are not mutually exclusive, and/or may be selectively omitted if not described as being necessarily required. Some of the drawings may include a scale (e.g., in units of mm) for indicating sizes of components illustrated therein. It is to be noted that the shown scales and component lengths are example and in no way limiting.

FIGS. 1A and 1B illustrate a perspective view and a top view of a sensor device 100, in accordance with the disclosure.

FIG. 2 is a block diagram of a circuitry 200 that may be included in a sensor device, in accordance with the disclosure.

FIGS. 3A to 3C illustrate output signals of various sensor devices.

FIG. 4 illustrates a top view of a sensor device 400, in accordance with the disclosure.

FIG. 5 illustrates a flowchart of a method for manufacturing a sensor device, in accordance with the disclosure.

FIG. 6 illustrates a flowchart of a method for sensing an electrical current, in accordance with the disclosure.

### DETAILED DESCRIPTION

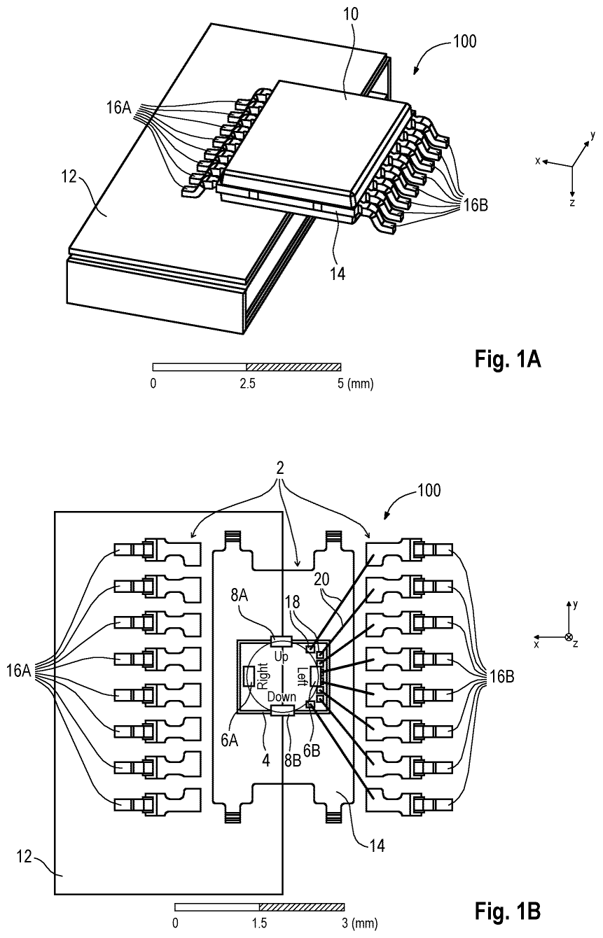

The sensor device 100 of FIGS. 1A and 1B may include an electrically conductive carrier 2 and a magnetic field sensor 4 mounted thereon. The magnetic field sensor 4 may include a first pair of sensing elements (or sensor elements) 6A, 6B and a second pair of sensing elements 8A, 8B. Optionally, the electrically conductive carrier 2 and the magnetic field sensor 4 may be at least partially encapsulated by an encapsulation material 10. The sensor device 100 may be arranged over (or mounted on) an electrical conductor 12 which may be regarded as a part of the sensor device 100 or not.

The magnetic field sensor 4 may be configured to provide differential signals as will be explained later on and may thus be referred to as differential magnetic field sensor. Differential sensing concepts as discussed herein may be configured to cancel homogeneous magnetic stray fields. Furthermore, the magnetic field sensor 4 may correspond to an integrated circuit or a semiconductor chip such that it may also be referred to as magnetic field sensor integrated circuit or magnetic field sensor chip. In the illustrated example, the upper main surface and the bottom main surface of the magnetic field sensor 4 may be arranged in the x-y-plane.

The first sensing elements 6A and 6B may be separated from each other in a first direction, e.g., a straight line connecting the first sensing elements 6A and 6B may be parallel to the first direction. In the illustrated example, the first direction may correspond to the x-direction. Each of the first sensing elements 6A and 6B may be sensitive to magnetic fields in the x-direction. That is, each of the first sensing elements 6A and 6B may be configured to sense the x-component of a magnetic field present at the location of the respective sensing element. In the following, the first sensing elements 6A and 6B may also be referred to as “right” and “left” sensing elements, respectively. Note that, due to the chosen coordinate system of FIG. 1B, the sensing element 6A on the left may be labeled as “right” sensing element, while the sensing element 6B on the right may be labeled as “left” sensing element 6B. However, a labeling of the sensing element 6A and 6B may be chosen differently in further examples.

In a similar fashion, the second sensing elements 8A and 8B may be separated from each other in a second direction that may be substantially perpendicular to the first direction. That is, a straight line connecting the second sensing elements 8A and 8B may be parallel to the second direction. In the illustrated example, the second direction may correspond to the y-direction. Each of the second sensing elements 8A and 8B may be sensitive to magnetic fields in the y-direction. That is, each of the second sensing elements 8A and 8B may be configured to sense the y-component of a magnetic field present at the location of the respective sensing element. In the following, the second sensing elements 8A and 8B may also be referred to as “up” and “down” sensing elements, respectively.

For example, the first sensing elements 6A, 6B and the second sensing elements 8A, 8B may be arranged in the x-y-plane, e.g., they may have an equal z-coordinate. In the illustrated case, a pitch (or distance) between the first sensing elements 6A and 6B may substantially equal a pitch between the second sensing elements 8A and 8B. Accordingly, the four sensing elements 6A, 6B and 8A, 8B may be arranged on a circle. In further examples, a pitch between the second sensing elements 8A and 8B may be increased or decreased such that the four sensing elements 6A, 6B and 8A, 8B may be arranged on an ellipse in such cases.

In one example, each of the sensing elements 6A, 6B and 8A, 8B may be implemented separately as a resistor bridge that may include an example number of four resistors. In general, the magnetic field sensor 4 and its sensing elements 6A, 6B and 8A, 8B are not restricted to a particular sensor technology. For example, the sensing elements 6A, 6B and 8A, 8B may be magnetoresistive xMR sensing elements, such as e.g., AMR sensing elements, GMR sensing elements, or TMR sensing elements. In this regard, the first sensing elements 6A, 6B and the second sensing elements 8A, 8B may correspond to in-plane magnetoresistive elements (or current-in-plane (CIP) magnetoresistive elements). In further examples, the sensing elements 6A, 6B and 8A, 8B may be implemented as Hall sensing elements or fluxgate sensing elements.

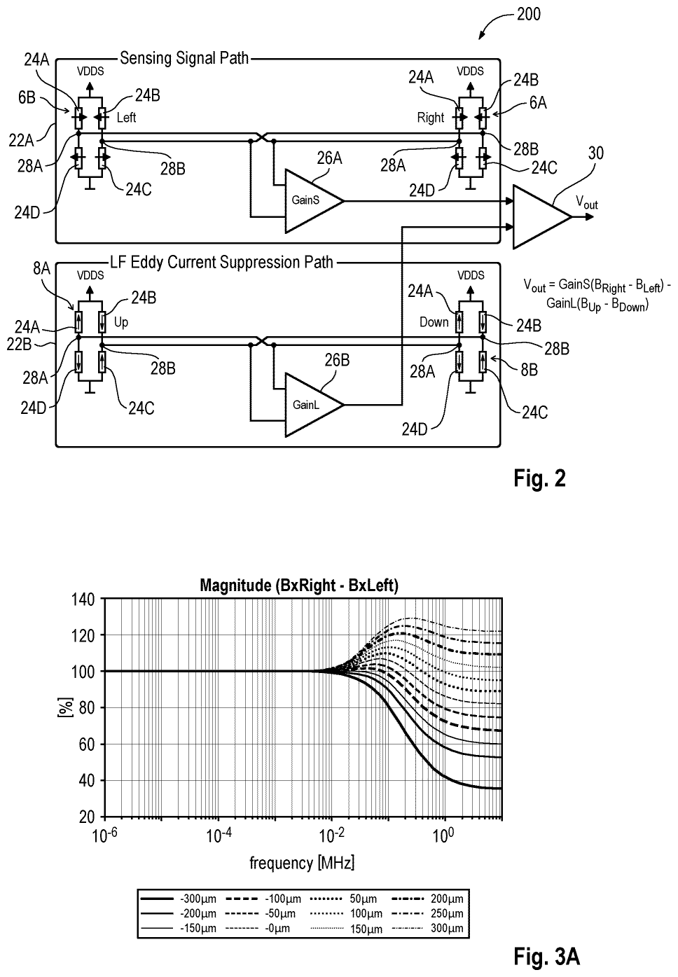

The sensing elements 6A, 6B and 8A, 8B may be integrated into a circuit of a chip. Such circuit may also be configured to perform at least one of signal amplification, analog-to-digital conversion, digital signal processing, or offset and temperature compensation. In addition to the components of the respective sensing element, components for signal amplification and/or analog-to-digital conversion may be regarded as part of the sensing elements 6A, 6B and 8A, 8B or not. Note that an example circuitry and a more detailed implementation of sensing elements is shown and discussed in connection with FIG. 2.

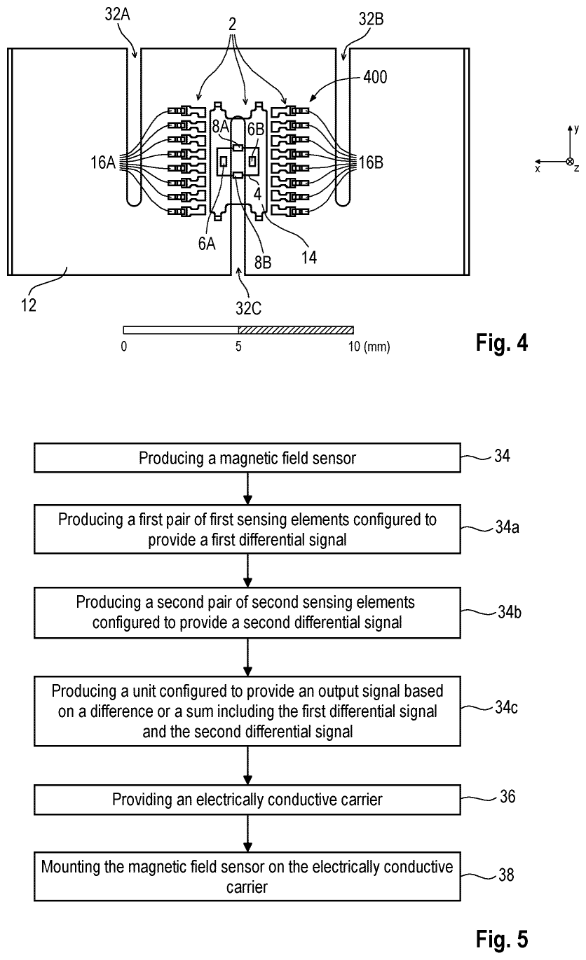

The electrical conductor 12 is not restricted to a specific type, shape or material and may be one of e.g., a conductor track, a printed circuit board track, a busbar, a current rail, or the like. In the illustrated case, the electrical conductor 12 may exemplarily correspond to a conductor track arranged on an upper surface of a multi-layer printed circuit board. The electrical conductor 12 of FIGS. 1A and 1B (or the illustrated portion thereof) may have a substantially linear shape and may exemplarily extend in the y-direction. In other examples, the electrical conductor 12 may have a different shape, such as e.g., a u-shape as shown and discussed in connection with the example of FIG. 4 described later on.

As can be seen from the top view of FIG. 1B, the electrical conductor 12 and the sensor device 100 may be aligned with respect to each other. In this regard, an edge of the electrical conductor 12 and a connecting line between the second sensing elements 8A and 8B may be aligned with respect to each other. More particular, the right edge of the electrical conductor 12 and the connecting line between the second sensing elements 8A and 8B may be congruent. Furthermore, the first sensing elements 6A and 6B may be symmetrically arranged with respect to the right edge of the electrical conductor 12. That is, the shortest distance between the sensing element 6A and the right edge of the electrical conductor 12 may substantially equal the shortest distance between the sensing element 6B and the right edge of the electrical conductor 12. A straight line connecting the sensing elements 6A and 6B may be substantially perpendicular to the right edge of the electrical conductor 12.

The electrically conductive carrier 2 is not restricted to a specific type, shape or material. For example, the carrier 2 may correspond to a leadframe that may be fabricated from metals and/or metal alloys, in particular at least one of copper, copper alloys, nickel, iron nickel, or the like. In the illustrated case, the leadframe 2 may exemplarily include one diepad 14 and two rows of leads (or pins or lead fingers) 16A, 16B arranged on opposite sides of the diepad 14. In further examples, a number and arrangement of diepads and leads may be chosen differently.

In the illustrated example, the diepad 14 may be arranged in the x-y-plane. The left edge and the right edge of the diepad 14 may extend in the y-direction, and the top edge and the bottom edge of the diepad 14 may at least partially extend in the x-direction. In the top view of FIG. 1B, a center (or geometric center) of the magnetic field sensor 4 and a center (or geometric center) of the electrically conductive carrier 2 (or of the diepad 14) may be congruent. Each row of leads 16A and 16B may include multiple leads arranged in parallel, wherein each of the leads 16A and 16B may substantially extend in the x-direction. In the non-limiting illustrated example, the leads 16A and 16B may be of a gull wing type and the sensor device 100 may correspond to a surface mounted device.

In the illustrated case, the magnetic field sensor 4 may be exemplarily arranged between the electrical conductor 12 and the electrically conductive carrier 2. In particular, the magnetic field sensor 4 may be mounted on the bottom surface of the diepad 14, e.g., the magnetic field sensor 4 may be mounted in a bottom die configuration. In further examples, the electrically conductive carrier 14 may alternatively be arranged between the electrical conductor 2 and the magnetic field sensor 4. In particular, the magnetic field sensor 4 may then be mounted in a top die configuration, e.g., the magnetic field sensor 4 may be mounted on the upper surface of the diepad 14.

The encapsulation material 10 may include or may be manufactured from at least one of a molding compound, an epoxy, a filled epoxy, a glass fiber filled epoxy, an imide, a thermoplast, a thermoset polymer, a polymer blend, a laminate, or the like. The encapsulation material 10 may be formed based on at least one of compression molding, injection molding, powder molding, liquid molding, map molding, laminating, or the like. The encapsulation material 10 may be configured to protect encapsulated device components against threats, such as e.g., mechanical impact, chemical contamination, light exposure, etc. In the illustrated example, the encapsulation material 10 may form a body or encapsulant having two opposite main surfaces extending in the x-y-plane. Due to such packaging the sensor device 100 may also be referred to as sensor package.

The electrically conductive carrier 2, the magnetic field sensor 4 and the leads 16A, 16B may be at least partially encapsulated in the encapsulation material 10. In contrast to this, the electrical conductor 12 may be a package external component, e.g., it may be arranged external to the encapsulation material 10. It is noted that, in the top view of FIG. 1B, the encapsulation material 10 is not shown for illustrative purposes so as not to obscure device components embedded therein.

Electrical contacts 18 of the magnetic field sensor chip 4 may be electrically connected to one or multiple of the leads 16B via electrical connection elements 20. In the illustrated example, the electrical connection elements 20 may correspond to wires. In further examples, the electrical connection elements 20 may include ribbons, clips, or the like. As can be seen from the perspective view of FIG. 1A, the leads 16A and 16B may at least partially protrude out of the encapsulation material 10 such that the encapsulated magnetic field sensor 4 may be electrically accessible from outside of the encapsulation material 10.

An example operation of the sensor device 100 is described below. During such operation an electrical current may flow through the electrical conductor 12. An output signal of the sensor device 100 based on a measurement of the sensing elements 6A, 6B and 8A, 8B may be used for determining the magnitude of the electrical current. In particular, the electrical current may be time-varying and may e.g., include or correspond to fast transient signals, high frequency AC signals, DC signals with ripple, or the like. In the illustrated example, the electrical conductor 12 may extend in the y-direction such that magnetic fields generated by electrical currents through the electrical conductor 12 may be located in the x-z-plane. In addition, in case of time-varying electrical currents, eddy currents may be induced in the electrically conductive carrier 2, in particular in the diepad 14.

The first pair of first sensing elements 6A and 6B may be configured to provide a first differential signal based on the magnetic field sensed at the locations of the first sensing elements 6A and 6B, respectively. In particular, the first differential signal may correspond to a difference B_{Right}−B_{Left}, wherein B_{Right} and B_{Left} may label the (x-components) of the sensed magnetic fields at the first sensing elements 6A and 6B (or the associated sensing signals), respectively. The magnetic fields at the locations of the first sensing elements 6A and 6B may include the magnetic field generated by the electrical current through the electrical conductor 12. In addition, the eddy currents induced in the electrically conductive carrier 2 (or in the diepad 14) may generate differential magnetic fields at the location of the first sensing elements 6A and 6B superimposed to the magnetic field of the external conductor 12. As a result, the first differential signal provided by the first sensing element 6A and 6B may be representative of the magnetic field generated by the electrical current through the electrical conductor 12 and by the eddy currents generated in the electrically conductive carrier 2.

In a similar fashion, the second pair of second sensing elements 8A and 8B may be configured to provide a second differential signal based on the magnetic field sensed at the locations of the second sensing elements 8A and 8B, respectively. In particular, the second differential signal may correspond to a difference B_{Up}−B_{Down}, wherein B_{Up} and B_{Down} may label the (y-components) of the sensed magnetic fields at the second sensing elements 8A and 8B (or the associated sensing signals), respectively. The magnetic field generated by the electrical current through the electrical conductor 12 may be located in the x-z-plane, but may not have a magnetic field component in the y-direction. Due to their sensitivity in the y-direction, the second sensing elements 8A and 8B may therefore not sense any magnetic field generated by the electrical current through the electrical conductor 12. As a result, the second differential signal provided by the second sensing element 8A and 8B may be representative of the magnetic field generated by the eddy currents and may be independent of the magnetic field generated by the electrical current through the electrical conductor 12.

As explained below the first and second differential signals may be used to provide an output signal independent of the magnetic field generated by the eddy currents. The output signal may be representative for the magnitude of the electrical current through the electrical conductor 12. For this purpose, the sensor device 100 may include a unit configured to provide an output signal based on a difference or a sum including the first differential signal and the second differential signal. It is noted that an example circuitry for providing such output signal is shown and described later on in connection with FIG. 2.

The induced eddy currents may flow in a circular (or elliptical) shape in the electrically conductive carrier 2, in particular in the x-y-plane of the diepad 14. Accordingly, the magnetic field generated by the eddy currents may generate differential magnetic fields at the locations of the first sensing elements 6A, 6B and at the locations of the second sensing elements 8A, 8B, respectively.

In case of a rotationally symmetric electrically conductive carrier (or leadframe) 2 (e.g., having the shape of a circle), the differential magnetic field at the first pair of sensing elements 6A, 6B and the differential magnetic field at the second pair of sensing elements 8A, 8B may be substantially of a same size. Therefore, by taking a difference of the first differential signal and the second differential signal, the signal component generated by the eddy currents may cancel out. That is, an effect of the induced eddy currents may be intrinsically suppressed, and a corresponding output signal Vₒᵤₜ of the sensor device 100 may be independent of the magnetic field generated by the eddy currents. The output signal Vₒᵤₜ may thus be representative for the electrical current through the electrical conductor 12. For the case of a rotationally symmetric carrier 2, the output signal Vₒᵤₜ may correspond to

$${V}_{out} = ( {B}_{R ight} - {B}_{Left} ) - ( {B}_{Up} - {B}_{D o w n} ) . \qquad ( 1 )$$

In case of a rotationally non-symmetric electrically conductive carrier (or leadframe) 2, the differential magnetic fields generated by the eddy currents at the locations of the first pair of sensing elements 6A, 6B and at the locations of the second pair of sensing elements 8A, 8B may not necessarily be of a same size. In such case, at least one of the first differential signal or the second differential signal may be scaled before taking the difference or sum of the two differential signals. For example, one or both of the differential signals may be scaled by using one or two variable gain amplifiers providing scaling factors, as e.g., shown and described in connection with FIG. 2. In general, the output signal Vₒᵤₜ may then correspond to

$${V}_{out} = GainS \cdot ( {B}_{Right} - {B}_{Left} ) - GainL \cdot ( {B}_{U p} - {B}_{D o w n} ) , \qquad ( 2 )$$

wherein GainS and GainL are scaling factors that may particularly depend on a geometry or shape of the electrically conductive carrier 2. In this way, a compensation of the contribution of the eddy currents may be adjusted to the specific geometry or shape of the electrically conductive carrier 2.

In a more particular case, for taking into account the geometry of the electrically conductive carrier 2, only the scaling factor GainL for the second pair of sensing elements 8A and 8B may be considered, while the scaling factor GainS for the first pair of sensing elements 6A and 6B may be discarded (or set to a value of one). The output signal Vₒᵤₜ may then correspond to

$${V}_{out} = ( {B}_{Right} - {B}_{Left} ) - GainL \cdot ( {B}_{U p} - {B}_{D o w n} ) . \qquad ( 3 )$$

As previously described various differences (or subtractions) of signals may need to be considered when determining an output signal Vₒᵤₜ. In this regard, it is to be noted that in some cases, a difference (or subtraction) of signals may be replaced by a corresponding sum of signals. For example, the difference B_{Right}−B_{Left} may need to be replaced by a sum B_{Right}+B_{Left}, when e.g., a sensitivity direction of the left sensing element 6B is inverted. Such sensitivity inversion may result in a sign change of the sensed value B_{Left}, which may then need to be considered accordingly by forming a sum instead of a difference. In a similar fashion, one or more differences specified by equations (1) to (3) may be replaced by corresponding sums, if changes in the sensitivities of one or more involved sensing elements may require such replacement.

Sensor devices in accordance with the disclosure may provide various technical effects as described below and may outperform conventional sensor devices in various aspects.

As previously discussed the sensor device 100 may provide an intrinsic scheme for compensating effects on the output signal resulting from induced eddy currents. Due to applying this compensation scheme the output signal of the sensor device 100 may not be deteriorated by occurring eddy currents. As a result, a higher overall accuracy of the sensor device 100 may be provided compared to conventional sensor devices.

In conventional sensor devices eddy currents induced in an electrically conductive carrier may be avoided by interrupting current paths of the eddy currents in the carrier. For this purpose, electrically conductive material of the carrier may be removed. For example, geometric features like cut-outs, slits, notches or cavities, typically arranged in close proximity to the sensing elements, may avoid the formation of eddy currents. Such carrier modifications may be achieved by tooling processes like stamping, etching, laser cutting, or the like. In particular, special tooling may be required which may be time consuming and may result in increased overall manufacturing costs. In addition, a requalification of a respective sensor device may be required any time a standard geometry of an electrically conductive carrier is replaced or modified.

In contrast to this, sensor devices in accordance with the disclosure may provide an intrinsic eddy current compensation scheme without the need of changing the geometric shape of the electrically conductive carrier. Referring back to the example of FIG. 1, the electrically conductive carrier 2 (and in particular the diepad 14) of the sensor device 100 may rather be free of any features configured to interrupt current paths of eddy currents. Compared to conventional sensor devices a fabrication of sensor devices in accordance with the disclosure may thus be less time consuming and less expensive. In addition, conventional device requalification may become obsolete. Rather, default sensor packages and/or standard geometries of electrically conductive carriers may be reused.

As previously discussed in connection with equations (2) and (3), a usage of scaling factors may provide a simple and quick adaption of the described eddy current compensation scheme to various device and carrier geometries. Sensor devices in accordance with the disclosure may thus be realized for a wide variety of device and carrier geometries.

Sensor devices in accordance with the disclosure may be used in connection with many industrial and automotive applications. In particular, the concepts described herein may be used in connection with any application relying on high accuracy and fast input signals. In this regard, typical applications may be e.g., high voltage eFuses, electric circuit breakers, or the like. Sensor devices described herein may be configured to be used in systems for detecting an electrical overcurrent event. In this context, a higher accuracy for measuring electrical currents may particularly avoid any unintended overcurrent detection activation.

The circuitry 200 of FIG. 2 may be included in a sensor device in accordance with the disclosure, such as e.g., the sensor device 100 of FIGS. 1A and 1B. For example, the elements of circuitry 200 may be integrated in a same semiconductor chip. The circuitry 200 may include a first (upper) signal path 22A and a second (bottom) signal path 22B. Referring back to the example of FIGS. 1A and 1B, the circuitry 200 may be configured to provide an output signal Vₒᵤₜ as e.g., specified by any of equations (1) to (3). In this context, the first signal path 22A and the second signal path 22B may be configured to provide a first differential signal and a second differential signal, respectively, thereby accounting for scaling factors that may depend on a shape of the electrically conductive carrier 2 as previously described.

The first signal path 22A may include a first pair of first sensing elements 6A and 6B which may be supplied by a supply voltage VDDS. For example, each of the first sensing elements 6A and 6B may include a bridge circuit (or resistor bridge). In the illustrated example, the respective bridge circuit may correspond to a Wheatstone bridge circuit including four resistors 24A to 24D. Each of the Wheatstone bridge circuits may have opposite or anti-parallel sensitivity directions in the individual branches of the bridge as indicated by arrows in the resistors 24A to 24D.

It is to be noted that an implementation of the first sensing elements 6A and 6B is not restricted to a specific design or type. In the illustrated example, the first sensing elements 6A and 6B may include two fully differential xMR bridges. In a further example, the first sensing elements 6A and 6B may include one spatially distributed differential xMR bridge. In yet a further example, the first sensing elements 6A and 6B may include one or more Hall sensing elements that may be spatially distributed.

The first signal path 22A may further include a first amplifier 26A configured to provide a gain factor GainS. The first amplifier 26A may be interconnected with the first sensing elements 6A and 6B (or the associated bridge circuits) as exemplarily shown in FIG. 2. In particular, a first (upper) input of the first gain amplifier 26A may be electrically coupled to a node 28A arranged between the two resistors 24A and 24D in the first branch of the first bridge circuit and to a node 28A arranged between the two resistors 24A and 24D in the first branch of the second bridge circuit. In addition, a second (bottom) input of the first gain amplifier 26A may be electrically coupled to a node 28B arranged between two resistors 24B and 24C in the second branch of the first bridge circuit and to a node 28B arranged between two resistors 24B and 24C in the second branch of the second bridge circuit.

Each of the first sensing elements 6A and 6B (or the associated bridge circuits) may be configured to provide a differential signal. For example, the differential signals may correspond to differential (in particular analog) output voltages. The differential signals may be provided to the inputs of the first amplifier 26A, respectively. Referring back to the example of FIG. 1, an output of the first amplifier 26A may correspond to the first differential signal representative of a magnetic field generated by an electrical current through the electrical conductor 12 and by eddy currents generated in the electrically conductive carrier 2. Note that the first amplifier 26A may be configured to amplify the first differential signal with the amplification factor GainS. That is, an output of the first amplifier 26A may be GainS. (B_{Right}−B_{Left}). The output may correspond to an (in particular analog) output voltage.

As can be seen from the example block diagram of FIG. 2, the second signal path 22B may be at least partially similar to the first signal path 22A. Compared to the first sensing elements 6A and 6B of the first signal path 22A, the resistors 24A to 24D of the second sensing elements 8A and 8B may have different sensitivity orientations. In particular, as compared to the resistors 24A to 24D of the first signal path 22A, the sensitivity directions of the resistors 24A to 24D in the second signal path 22B may be rotated counterclockwise by an angle of 90 degrees.

Each of the second sensing elements 8A and 8B (or the associated bridge circuits) may be configured to provide a differential signal. The differential signals may be provided to the inputs of a second amplifier 26B, respectively. Referring back to the example of FIG. 1, an output of the second amplifier 26B may correspond to the second differential signal representative of a magnetic field generated by the eddy currents and independent of a magnetic field generated by the electrical current through the electrical conductor 12. Note that the second amplifier 26B may be configured to amplify the second differential signal by an amplification factor GainL. Referring back to the example of FIGS. 1A and 1B, the amplification factor GainL of the second amplifier 26B may particularly be based on a shape or geometry of the electrically conductive carrier 2. An output of the second amplifier 26B may thus be GainL. (B_{Up}−B_{Down}). The output may correspond to an (in particular analog) output voltage.

The circuitry 200 may further include a third amplifier 30. An output of the first amplifier 26A may be coupled to a first (upper) input of the third amplifier 30. In a similar fashion, an output of the second amplifier 26B may be coupled to a second (bottom) input of the third amplifier 30. The third amplifier 30 may be configured to output a difference of the signals applied to its two inputs. For example, an output may correspond to an (in particular analog) output voltage. In the illustrated example, an output Vₒᵤₜ of the third amplifier 30 may be

$${V}_{out} = GainS \cdot ( {B}_{Right} - {B}_{Left} ) - GainL \cdot ( {B}_{U p} - {B}_{D o w n} ) . \qquad ( 4 )$$

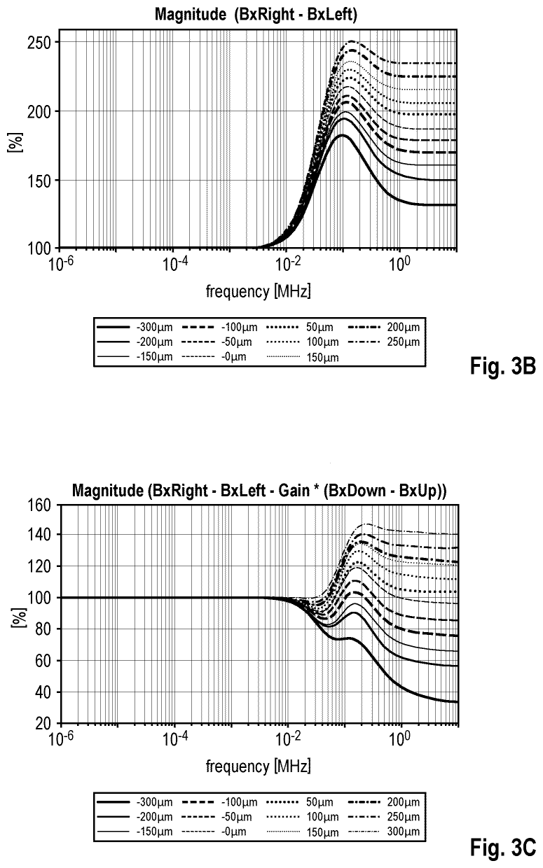

FIGS. 3A to 3C illustrate output signals of various sensor devices. The illustrated output signals were obtained by using a simulation software for the calculation of electric and magnetic fields. Each of FIGS. 3A to 3C includes multiple graphs relating to different x-displacements of the magnetic field sensor 4 with respect to the right edge of the electrical conductor 12 (see e.g., FIG. 1B). In this regard, an x-displacement of 0 μm relates to the scenario of FIG. 1B. Furthermore, an x-displacement of e.g., +100 μm (−100 μm) relates to the scenario of FIG. 1B with the magnetic field sensor 4 being displaced in the positive (negative) x-direction by a distance of 100 μm. It is to be noted that the discussed x-displacements of the magnetic field sensor 4 may be undesired and may particularly occur due to assembly tolerances.

FIG. 3A shows output signals of a sensor device including a non-conductive carrier. Since no eddy currents may occur in the non-conductive carrier, the output signal is independent of any effects that may have been generated in a similar device including an electrically conductive carrier. In this regard, the scenario of FIG. 3A may be regarded as ideal. The magnitude of the output signal B_{xRight}−B_{xLeft} is plotted against the frequency (of e.g., fast transient signals). Changes in the output signals at higher frequency may be purely related to the skin effect in the external electrical conductor 12.

FIG. 3B shows output signals of a sensor device including an electrically conductive leadframe in which eddy currents may be induced. The magnitude of the output signal B_{xRight}−B_{xLeft} is plotted against the frequency (of e.g., fast transient signals). As can be seen from FIG. 3B, eddy currents induced in the leadframe may cause a significant amplification at higher frequencies which may result in reduced accuracy of the measurement signals and potential false activation of overcurrent detection.

FIG. 3C shows output signals of a sensor device including an electrically conductive leadframe in which eddy currents may occur, but may be compensated based on the compensation scheme as previously described. An example scaling factor GainL of 3.5 was applied. Comparing the scenarios of FIGS. 3A and 3C, the benefit of the applied compensation scheme becomes apparent. In the scenario of FIG. 3C, an effect of eddy currents induced in the leadframe may be widely reduced.

The sensor device 400 of FIG. 4 may include some or all features of the sensor device 100 of FIG. 1. All comments made in connection with previously described examples may also hold true for the example of FIG. 4 and are not discussed again for the sake of simplicity. An operation of the sensor device 400 may be similar to an operation of previously described sensor devices.

In comparison to the example of FIGS. 1A and 1B the electrical conductor 12 of FIG. 4 may have a different shape. In the top view of FIG. 4, the electrical conductor 12 may substantially have the shape of a rectangle including two notches 32A and 32B extending from the upper edge of the electrical conductor 12 in the negative y-direction and a third notch 32C extending from the bottom edge of the electrical conductor 12 in the positive y-direction.

In an area between the two notches 32A and 32B, the electrical conductor 12 may include a u-shaped portion. The u-shaped portion of the electrical conductor 12 may include a first section arranged on the left and extending in the y-direction and a second section arranged on the right and extending in the y-direction. In addition, the u-shaped portion of the electrical conductor 12 may include a third section extending in the x-direction direction and connecting the first section and the second section.

The u-shaped portion of the electrical conductor 12 and the sensor device 400 may be aligned with respect to each other. In this regard, the sensing element 6A of the first pair of sensing elements 6A, 6B may be arranged over the first section of the u-shaped portion, and the second sensing element 6B of the first pair of sensing elements 6A, 6B may be arranged over the second section of the u-shaped portion. Furthermore, the second pair of sensing elements 8A and 8B may be arranged between the first section and the second section of the u-shaped portion, e.g., they may be arranged over the third notch 32C.

FIG. 5 illustrates a flowchart of a method for manufacturing a sensor device in accordance with the disclosure. The method may be used for manufacturing any of the previously described sensor devices and may thus be read in connection with preceding figures. The following description uses reference numerals of previously described examples. The method is illustrated in a general manner in order to qualitatively specify aspects of the present disclosure. The method may be extended by one or multiple aspects described in connection with other examples.

At 34, a magnetic field sensor 4 may be produced. Producing the magnetic field sensor 4 may include an act 34a of producing a first pair of first sensing elements 6A and 6B configured to provide a first differential signal, wherein the first sensing elements 6A and 6B are separated from each other in a first direction, and wherein each of the first sensing elements 6A and 6B is sensitive to magnetic fields in the first direction. Producing the magnetic field sensor 4 may further include an act 34b of producing a second pair of second sensing elements 8A and 8B configured to provide a second differential signal, wherein the second sensing elements 8A and 8B are separated from each other in a second direction perpendicular to the first direction, and wherein each of the second sensing elements 8A and 8B is sensitive to magnetic fields in the second direction. Producing the magnetic field sensor 4 may further include an act 34c of producing a unit configured to provide an output signal based on a difference or a sum including the first differential signal and the second differential signal. At 36, an electrically conductive carrier 2 may be provided. At 38, the magnetic field sensor 4 may be mounted on the electrically conductive carrier 2.

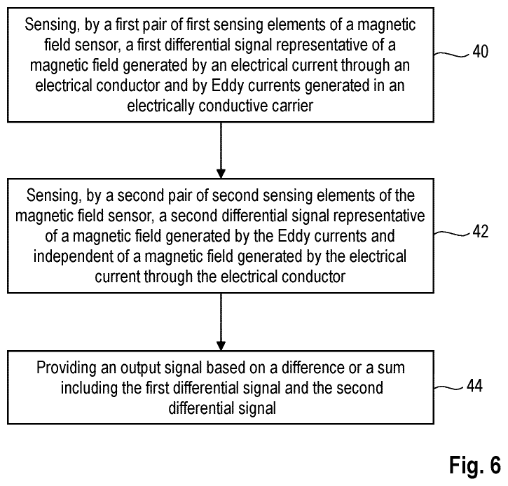

FIG. 6 illustrates a flowchart of a method in accordance with the disclosure. The method may be performed by any of the previously described sensor devices and may thus be read in connection with preceding figures. The following description uses reference numerals of previously described examples. The method may be applied for sensing an electrical current through an electrical conductor 12 by a magnetic field sensor 4 mounted on an electrically conductive carrier 2. The method is illustrated in a general manner in order to qualitatively specify aspects of the present disclosure. The method may be extended by one or multiple aspects described in connection with other examples.

At 40, a first differential signal representative of a magnetic field generated by the electrical current through the electrical conductor 12 and by eddy currents generated in the electrically conductive carrier 2 may be sensed by a first pair of first sensing elements 6A and 6B of the magnetic field sensor 4. At 42, a second differential signal representative of a magnetic field generated by the eddy currents and independent of a magnetic field generated by the electrical current through the electrical conductor 12 may be sensed by a second pair of second sensing elements 8A and 8B of the magnetic field sensor 4. At 44, an output signal may be provided based on a difference or a sum including the first differential signal and the second differential signal.

### ASPECTS

In the following, sensor devices, methods for manufacturing sensor devices and methods for sensing electrical currents are explained using aspects.

Aspect 1 is a sensor device, comprising: an electrically conductive carrier; a magnetic field sensor mounted on the electrically conductive carrier, wherein the magnetic field sensor comprises: a first pair of first sensing elements configured to provide a first differential signal representative of a magnetic field generated by an electrical current through an electrical conductor and by eddy currents generated in the electrically conductive carrier, and a second pair of second sensing elements configured to provide a second differential signal representative of a magnetic field generated by the eddy currents and independent of a magnetic field generated by the electrical current through the electrical conductor; and a unit configured to provide an output signal based on a difference or a sum including the first differential signal and the second differential signal.

Aspect 2 is a sensor device according to Aspect 1, wherein the output signal is independent of the magnetic field generated by the eddy currents.

Aspect 3 is a sensor device according to Aspect 1 or 2, wherein: the first sensing elements are separated from each other in a first direction and each of the first sensing elements is sensitive to magnetic fields in the first direction, and the second sensing elements are separated from each other in a second direction perpendicular to the first direction and each of the second sensing elements is sensitive to magnetic fields in the second direction.

Aspect 4 is a sensor device according to Aspect 3, wherein the electrical conductor extends in the second direction.

Aspect 5 is a sensor device according to Aspect 3 or 4, wherein an edge of the electrical conductor and a connecting line between the second sensing elements are congruent when viewed in a third direction perpendicular to the first direction and the second direction.

Aspect 6 is a sensor device according to Aspect 5, wherein the first sensing elements are symmetrically arranged with respect to the edge of the electrical conductor.

Aspect 7 is a sensor device according to Aspect 3, wherein the electrical conductor comprises a u-shaped electrical conductor.

Aspect 8 is a sensor device according to Aspect 7, wherein the u-shaped electrical conductor comprises: a first section and a second section extending in the second direction, and a third section extending in the first direction and connecting the first section and the second section.

Aspect 9 is a sensor device according to Aspect 8, wherein, when viewed in a third direction perpendicular to the first direction and the second direction: a first sensing element of the first pair of sensing elements is arranged over the first section and the second sensing element of the first pair of sensing elements is arranged over the second section, and the second pair of sensing elements is arranged between the first section and the second section.

Aspect 10 is a sensor device according to one of Aspects 3 to 9, wherein the electrically conductive carrier is arranged in a plane defined by the first direction and the second direction.

Aspect 11 is a sensor device according to one of Aspects 3 to 10, wherein a center of the magnetic field sensor and a center of the electrically conductive carrier are congruent when viewed in a third direction perpendicular to the first direction and the second direction.

Aspect 12 is a sensor device according to one of the preceding Aspects, further comprising: an amplifier configured to amplify the second differential signal, wherein an amplification factor of the amplifier is based on a shape of the electrically conductive carrier.

Aspect 13 is a sensor device according to one of the preceding Aspects, wherein: a first one of the second sensing elements comprises a first bridge circuit including a first branch and a second branch, the second one of the second sensing elements comprises a second bridge circuit including a first branch and a second branch, a first input of the gain amplifier is electrically coupled to a node arranged between two resistors in the first branch of the first bridge circuit and to a node arranged between two resistors in the first branch of the second bridge circuit, and a second input of the gain amplifier is electrically coupled to a node arranged between two resistors in the second branch of the first bridge circuit and to a node arranged between two resistors in the second branch of the second bridge circuit.

Aspect 14 is a sensor device according to one of the preceding Aspects, wherein the magnetic field sensor is arranged between the electrical conductor and the electrically conductive carrier.

Aspect 15 is a sensor device according to one of the preceding Aspects, wherein the electrically conductive carrier is free of any features configured to interrupt current paths of the eddy currents.

Aspect 16 is a sensor device according to one of the preceding Aspects, wherein: the magnetic field sensor is encapsulated in an encapsulation material, and the electrical conductor is arranged external to the encapsulation material.

Aspect 17 is a sensor device according to one of the preceding Aspects, wherein the sensor device is configured to be used in a system for detecting an electrical overcurrent event.

Aspect 18 is a sensor device, comprising: an electrically conductive carrier; a magnetic field sensor mounted on the electrically conductive carrier, wherein the magnetic field sensor comprises: a first pair of first sensing elements configured to provide a first differential signal, wherein the first sensing elements are separated from each other in a first direction, and wherein each of the first sensing elements is sensitive to magnetic fields in the first direction, and a second pair of second sensing elements configured to provide a second differential signal, wherein the second sensing elements are separated from each other in a second direction perpendicular to the first direction, and wherein each of the second sensing elements is sensitive to magnetic fields in the second direction; and a unit configured to provide an output signal based on a difference or a sum including the first differential signal and the second differential signal.

Aspect 19 is a sensor device according to Aspect 18, wherein: the first differential signal is representative of a magnetic field generated by an electrical current through an electrical conductor and by eddy currents generated in the electrically conductive carrier, and the second differential signal is representative of a magnetic field generated by the eddy currents and independent of a magnetic field generated by the electrical current through the electrical conductor, and the output signal is independent of the magnetic field generated by the eddy currents.

Aspect 20 is a sensor device according to Aspect 18 or 19, wherein the first sensing elements and the second sensing elements are arranged on a circle or an ellipse.

Aspect 21 is a sensor device according to one of Aspects 18 to 20, wherein the first sensing elements and the second sensing elements are in-plane magnetoresistive elements.

Aspect 22 is a method for sensing an electrical current through an electrical conductor by a magnetic field sensor mounted on an electrically conductive carrier, the method comprising: sensing, by a first pair of first sensing elements of the magnetic field sensor, a first differential signal representative of a magnetic field generated by the electrical current through the electrical conductor and by eddy currents generated in the electrically conductive carrier; sensing, by a second pair of second sensing elements of the magnetic field sensor, a second differential signal representative of a magnetic field generated by the eddy currents and independent of a magnetic field generated by the electrical current through the electrical conductor; and providing an output signal based on a difference or a sum including the first differential signal and the second differential signal.

Aspect 23 is a method for manufacturing a sensor device, the method comprising: producing a magnetic field sensor, wherein producing the magnetic field sensor comprises: producing a first pair of first sensing elements configured to provide a first differential signal, wherein the first sensing elements are separated from each other in a first direction, and wherein each of the first sensing elements is sensitive to magnetic fields in the first direction, and producing a second pair of second sensing elements configured to provide a second differential signal, wherein the second sensing elements are separated from each other in a second direction perpendicular to the first direction, and wherein each of the second sensing elements is sensitive to magnetic fields in the second direction; producing a unit configured to provide an output signal based on a difference or a sum including the first differential signal and the second differential signal; providing an electrically conductive carrier; and mounting the magnetic field sensor on the electrically conductive carrier.

While the present disclosure has been described with reference to illustrative aspects, this description is not intended to be construed in a limiting sense. Various modifications and combinations of the illustrative aspects, as well as other aspects of the disclosure, will be apparent to persons skilled in the art upon reference of the description. It is therefore intended that the appended claims encompass any such modifications or aspects.

1. A sensor device, comprising:
an electrically conductive carrier;
a magnetic field sensor mounted on the electrically conductive carrier, wherein the magnetic field sensor comprises:
a first pair of first sensing elements configured to provide a first differential signal representative of a magnetic field generated by an electrical current through an electrical conductor and by eddy currents generated in the electrically conductive carrier, and
a second pair of second sensing elements configured to provide a second differential signal representative of a magnetic field generated by the eddy currents and independent of the magnetic field generated by the electrical current through the electrical conductor; and
a unit configured to provide an output signal based on a difference or a sum including the first differential signal and the second differential signal.

2. The sensor device of claim 1, wherein the output signal is independent of the magnetic field generated by the eddy currents.

3. The sensor device of claim 1, wherein:
the first pair of sensing elements are separated from each other in a first direction and each of the first pair of sensing elements is sensitive to magnetic fields in the first direction, and
the second pair of sensing elements are separated from each other in a second direction perpendicular to the first direction and each of the second pair of sensing elements is sensitive to magnetic fields in the second direction.

4. The sensor device of claim 3, wherein the electrical conductor extends in the second direction.

5. The sensor device of claim 3, wherein an edge of the electrical conductor and a connecting line between the second pair of sensing elements are congruent when viewed in a third direction perpendicular to the first direction and the second direction, and wherein the first pair of sensing elements are symmetrically arranged with respect to the edge of the electrical conductor.

6. (canceled)

7. The sensor device of claim 3, wherein the electrical conductor comprises a u-shaped electrical conductor.

8. The sensor device of claim 7, wherein the u-shaped electrical conductor comprises:
a first section and a second section extending in the second direction, and
a third section extending in the first direction and connecting the first section and the second section.

9. The sensor device of claim 8, wherein, when viewed in a third direction perpendicular to the first direction and the second direction:
a first sensing element of the first pair of sensing elements is arranged over the first section and a second sensing element of the first pair of sensing elements is arranged over the second section, and
the second pair of sensing elements is arranged between the first section and the second section.

10. The sensor device of claim 3, wherein the electrically conductive carrier is arranged in a plane defined by the first direction and the second direction.

11. The sensor device of claim 3, wherein a center of the magnetic field sensor and a center of the electrically conductive carrier are congruent when viewed in a third direction perpendicular to the first direction and the second direction.

12. The sensor device of claim 1, further comprising:
an amplifier configured to amplify the second differential signal, wherein an amplification factor of the amplifier is based on a shape of the electrically conductive carrier.

13. The sensor device of claim 12, wherein:
a first one of the second pair of sensing elements comprises a first bridge circuit including a first branch and a second branch,
a second one of the second pair of sensing elements comprises a second bridge circuit including a first branch and a second branch,
a first input of the amplifier is electrically coupled to a node arranged between two resistors in the first branch of the first bridge circuit and to a node arranged between two resistors in the first branch of the second bridge circuit, and
a second input of the amplifier is electrically coupled to a node arranged between two resistors in the second branch of the first bridge circuit and to a node arranged between two resistors in the second branch of the second bridge circuit.

14. The sensor device of claim 1, wherein the magnetic field sensor is arranged between the electrical conductor and the electrically conductive carrier, and wherein the electrically conductive carrier is free of any features configured to interrupt current paths of the eddy currents.

15. (canceled)

16. The sensor device of claim 1, wherein:
the magnetic field sensor is encapsulated in an encapsulation material, and
the electrical conductor is arranged external to the encapsulation material.

17. The sensor device of claim 1, wherein the sensor device is configured to be used in a system for detecting an electrical overcurrent event.

18. A sensor device, comprising:
an electrically conductive carrier;
a magnetic field sensor mounted on the electrically conductive carrier, wherein the magnetic field sensor comprises:
a first pair of first sensing elements configured to provide a first differential signal, wherein the first sensing elements are separated from each other in a first direction, and wherein each of the first sensing elements is sensitive to magnetic fields in the first direction, and
a second pair of second sensing elements configured to provide a second differential signal, wherein the second sensing elements are separated from each other in a second direction perpendicular to the first direction, and wherein each of the second sensing elements is sensitive to magnetic fields in the second direction; and
a unit configured to provide an output signal based on a difference or a sum including the first differential signal and the second differential signal.

19. The sensor device of claim 18, wherein:
the first differential signal is representative of a magnetic field generated by an electrical current through an electrical conductor and by eddy currents generated in the electrically conductive carrier, and
the second differential signal is representative of a magnetic field generated by the eddy currents and independent of the magnetic field generated by the electrical current through the electrical conductor, and
the output signal is independent of the magnetic field generated by the eddy currents.

20. The sensor device of claim 18, wherein the first pair of first sensing elements and the second pair of second sensing elements are arranged on a circle or an ellipse.

21. The sensor device of claim 18, wherein the first pair of sensing elements and the second pair of sensing elements are in-plane magnetoresistive elements.

22. A method for sensing an electrical current through an electrical conductor by a magnetic field sensor mounted on an electrically conductive carrier, the method comprising:
sensing, by a first pair of first sensing elements of the magnetic field sensor, a first differential signal representative of a magnetic field generated by the electrical current through the electrical conductor and by eddy currents generated in the electrically conductive carrier;
sensing, by a second pair of second sensing elements of the magnetic field sensor, a second differential signal representative of a magnetic field generated by the eddy currents and independent of the magnetic field generated by the electrical current through the electrical conductor; and
providing an output signal based on a difference or a sum including the first differential signal and the second differential signal.

23. (canceled)
